(19) United States
(12) Patent Application Publication
(10) Pub. No.: US 2019/0096485 A1
(43) Pub. Date: Mar. 28, 2019

(54) CONTROLLER, SEMICONDUCTOR MEMORY DEVICE, AND MEMORY SYSTEM HAVING THE SAME

(71) Applicant: SK hynix Inc., Gyeonggi-do (KR)

(72) Inventors: Won Jin JUNG, Gyeonggi-do (KR); Keun Woo LEE, Gyeonggi-do (KR)

(21) Appl. No.: 15/962,460

(22) Filed: Apr. 25, 2018

(30) Foreign Application Priority Data
Sep. 22, 2017 (KR) 10-2017-0122393

(51) Int. Cl. G11C 16/04; G11C 16/34; G11C 7/02; G11C 11/406; G11C 7/10; G06F 12/02; G06F 12/06; G06F 11/07

(52) U.S. Cl. CPC G11C 16/0483; G11C 16/3418; G11C 7/02; G11C 11/40618; G06F 11/0793; G06F 12/0246; G06F 12/0638; G06F 11/076; G11C 7/1006

(57) ABSTRACT

A controller which controls an operation of a semiconductor memory device including a plurality of memory blocks. The controller includes a randomizer. The randomizer generates randomized data, based on a block address of a target memory block, and a program-erase count value or the target memory block. Accordingly, the performance of a memory system is improved.

### CROSS-REFERENCE TO RELATED APPLICATION

The present application claims priority under 35 U.S.C. § 119(a) to Korean patent application number 10-2017-0122393, filed on Sep. 22, 2017, which is herein incorporated by reference in its entirety.

### BACKGROUND

### 1. Field of Invention

An aspect of the present disclosure relates to an electronic device, and more particularly, to a controller, a semiconductor memory device, and a memory system having the same.

### 2. Description of the Related Art

Memory devices may be formed in a two-dimensional structure in which strings are arranged horizontally to a semiconductor substrate, or be formed in a three-dimensional structure in which strings are arranged vertically to a semiconductor substrate. A three-dimensional semiconductor device is a memory device devised in order to overcome the limit of degree of integration in two-dimensional semiconductor devices, and may include a plurality of memory cells vertically stacked on a semiconductor substrate.

### SUMMARY

Embodiments provide a controller, a semiconductor memory device, and a memory system having the same with improved performance.

According to an aspect of the present disclosure, there is provided a controller for controlling an operation of a semiconductor memory device including a plurality memory blocks, the controller including a randomizer, wherein the randomizer generates randomized data, based on a block address of a target memory block, and a program-erase count value of the target memory block.

The randomizer may include: a first randomizing circuit configured to receive original data from a host, receive a randomizing seed corresponding to the block address, and generate temporary data; and a second randomizing circuit configured to receive the temporary data and the program-erase count value, and generate the randomizing data.

The first randomizing circuit may generate the temporary data by performing an operation on the randomizing seed and the original data.

The second randomizing circuit may invert the temporary data, based on the program-erase count value, and output the inverted result as the randomized data.

The second randomizing circuit may include: an inverter configured to invert the temporary data and output the inverted result as inverted temporary data; and a multiplexer configured to receive the temporary data and the inverted temporary data, and output any one of the temporary data and the inverted temporary data as the randomized data, based on the program-erase count value.

The randomizer may include: a seed conversion circuit configured to convert a randomizing seed corresponding to the block address, based on the program-erase count value, and output the converted randomizing seed as a conversion seed; and a randomizing circuit configured to receive original data from a host, receive the conversion seed from the seed conversion circuit, and generate the randomized data.

The seed conversion circuit may add the program-erase count value to the randomizing seed, and output the added result as the conversion seed.

The randomizing circuit may perform an operation on the conversion seed and the original data, and output the operated result as the randomized data.

According to an aspect of the present disclosure, there is provided a semiconductor memory device including: a memory cell array including a plurality of memory blocks having a plurality of memory cells programmed to have any one program state among a plurality of program states distinguished from each other based on threshold voltages; a peripheral circuit configured to perform a program operation including a program voltage applying operation and a verify operation on the plurality of memory cells; a control logic configured to control an operation of the peripheral circuit; and a data converter configured to convert data received from a controller, based on the control of the control logic, wherein the control logic determines whether the received data is to be converted based on a program-erase count value of a memory block to which received data is to be written.

The data converter may invert received data, based on the determination of the control logic, and output the inverted data to the peripheral circuit.

The control logic may generate a conversion control signal, based on the program-erase count value.

The data converter may include: an inverter configured to invert received data and output the inverted result as inverted data; and a multiplexer configured to receive the received data and the inverted data, and output any one of the received data and the inverted data to the peripheral circuit, based on the conversion control signal.

According to an aspect of the present disclosure, there is provided a memory system including: a semiconductor memory device including a plurality of memory blocks; and a controller configured to control an operation of the semiconductor memory device, wherein original data from a host is converted based on a block address of a target memory block and a program-erase count value of the target memory block, and the converted data is written to the target memory block.

The controller may include a randomizer, and the randomizer may generate randomized data, based on the block address and the program-erase count value.

The semiconductor memory device may write the randomized data to the target memory block.

The randomizer may generate temporary data by performing an operation on a randomizing seed and the original data. The randomizer may invert the temporary data, based on the program-erase count value, and output the inverted result as the randomized data.

The randomizer may generate a conversion seed by converting a randomizing seed corresponding to the block address, based on the program-erase count value. The randomizer may perform an operation on the conversion seed and the original data, and output the operated result as the randomized data.

The controller may randomize the original data, based on the block address. The semiconductor memory device may invert the randomized data, based on the program-erase count value, and write the inverted data to the target memory block.

When the program-erase count value is even, the semiconductor memory device may write the randomized data to the target memory block. When the program-erase count value is odd, the semiconductor memory device may invert the randomized data and then write the inverted data to the target memory block.

When the program-erase count value is odd, the semiconductor memory device may write the randomized data to the target memory block. When the program-erase count value is even, the semiconductor memory device may invert the randomized data and then write the inverted data to the target memory block.

According to an aspect of the present disclosure, there is provided a memory system including: a memory device including a memory block; and a controller. The controller is suitable for randomizing data; converting the randomized data according to a current status of the memory block; and controlling the memory device to program the converted data into the memory block.

According to an aspect of the present disclosure, there is provided a memory system including a memory device including a memory block; and a controller. The controller is suitable for converting seed data according to a current status of the memory block; randomizing data by using the converted seed data; and controlling the memory device to program the randomized data into the memory block.

According to an aspect of the present disclosure, there is provided a memory system including a memory device including a memory block; and a controller suitable for providing randomized data to the memory device. The memory device converts the randomized data according to a current status of the memory block, and programs the converted data into the memory block.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a controller, a semiconductor memory device, and a memory system including the same according to an embodiment of the present disclosure.

FIG. 2 is a block diagram illustrating the semiconductor memory device shown in FIG. 1.

FIG. 3 is a diagram illustrating an embodiment of a memory cell array shown in FIG. 2.

FIG. 4 is a circuit diagram illustrating any one memory block among memory blocks shown in FIG. 3.

FIG. 5 is a circuit diagram illustrating an embodiment of the one memory block among the memory blocks shown in FIG. 3.

FIG. 6 is a circuit diagram illustrating an embodiment of one memory block among a plurality of memory blocks included in the memory cell array shown in FIG. 2.

FIG. 7 is a block diagram illustrating an operation of a randomizer shown in FIG. 1.

FIG. 8 is a block diagram illustrating an exemplary embodiment of the randomizer shown in FIG. 7.

FIG. 9 is a block diagram illustrating an exemplary embodiment of a second randomizing circuit shown in FIG. 8.

FIG. 10 is a block diagram illustrating an exemplary embodiment of the randomizer shown in FIG. 7.

FIG. 11 is a block diagram illustrating an exemplary embodiment of a seed conversion circuit shown in FIG. 10.

FIG. 12 is a block diagram illustrating an exemplary embodiment of the semiconductor memory device in accordance with the embodiment of the present disclosure.

FIG. 13 is a block diagram illustrating an exemplary embodiment of a data converter shown in FIG. 12.

FIG. 14 is a flowchart illustrating an operating method of a memory controller in accordance with an embodiment of the present disclosure.

FIG. 15 is a flowchart illustrating in more detail an embodiment of a step of randomizing program data, shown in FIG. 14.

FIG. 16 is a flowchart illustrating in more detail embodiment of the step of randomizing the program data, shown in FIG. 14.

FIG. 17 is a flowchart illustrating an operating method of a semiconductor memory device in accordance with an embodiment of the present disclosure.

FIG. 18 is a flowchart illustrating in more detail an embodiment of a step of converting program data, shown in FIG. 17.

FIG. 19 is a block diagram illustrating an embodiment of the memory system shown in FIG. 1.

FIG. 20 is a block diagram illustrating an application example of the memory system shown in FIG. 19.

FIG. 21 is a block diagram illustrating a computing system including the memory system described with reference to FIG. 20.

### DETAILED DESCRIPTION

In the following detailed description, only certain exemplary embodiments of the present disclosure have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless there is different disclosure.

Hereinafter, exemplary embodiments of the present disclosure will be described in detail with reference to the accompanying drawings. The same reference numerals are used to designate the same elements as those shown in other drawings. In the following descriptions, only the portions necessary for understanding operations according to the exemplary embodiments may be described, and descriptions of the other portions may be omitted so as to not obscure important concepts of the embodiments.

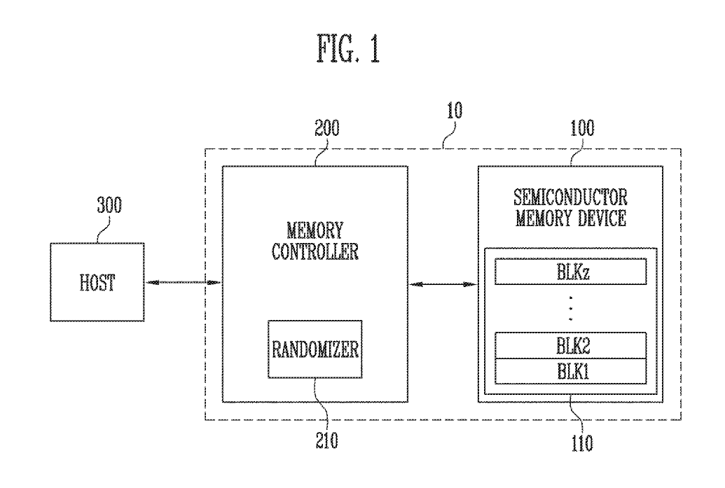

FIG. 1 is a block diagram illustrating a controller, a semiconductor memory device, and a memory system including the same in accordance with an embodiment of the present disclosure.

Referring to FIG. 1, the memory system 10 may include a semiconductor memory device 100 and a memory controller 200. The semiconductor memory device 100 may include a memory cell array 110.

The memory cell array 110 includes a plurality of memory areas. The plurality of memory areas may be a plurality of memory blocks BLK1 to BLKz as shown in FIG. 1. Here, each of the memory blocks is a unit of erasure. Each of the plurality of memory blocks BLK1 to BLKz may include a plurality of memory cells.

The semiconductor memory device 100 operates under the control of the controller 200.

The semiconductor memory device 100 may write data to the memory cell array 110 in response to a write request from the controller 200. If a write command, an address, and data are received as the write request from the controller, the semiconductor memory device 100 may write the data to memory cells indicated by the address.

The semiconductor memory device 100 performs a read operation in response to a read request from the controller 200. If a read command and an address are received as the read request from the controller 200, the semiconductor memory device 100 reads data from memory cells indicated by the address and outputs the read data to the controller 200.

In an embodiment, the semiconductor memory device 100 may be a flash memory device. However, it will be understood that the scope of the present disclosure is not limited to the flash memory device. In some embodiments, the semiconductor memory device 100 may be a double data rate synchronous dynamic random access memory (DDR SDRAM), a low power double data rate 4 (LPDDR4) SDRAM, a graphics double data rate (GDDR) SRAM, a low power DDR (LPDDR), a rambus dynamic random access memory (RDRAM), a NAND flash memory, a vertical NAND flash memory, a NOR flash memory, a resistive random access memory (RRAM), a phase-change memory (PRAM), a magnetoresistive random access memory (MRAM), a ferroelectric random access memory (FRAM), a spin transfer torque random access memory (STT-RAM), or the like.

In an embodiment, the semiconductor memory device 100 may be implemented in a three-dimensional array structure. The present disclosure may be applied to not only a flash memory device in which a charge storage layer is configured with a floating gate (FG) but also a charge trap flash (CTF) in which a charge storage layer is configured with an insulating layer.

The controller 200 is coupled between the semiconductor memory device 100 and a host 300. The controller 200 is configured to interface with the host 300 and the semiconductor memory device 100. The controller 200 may transmit a write request or a read request to the semiconductor memory device 100 under the control of the host 300.

The controller 200 includes a ramdomizer 210. The randomizer 210 may be activated in a write operation. If a block address of a target memory block is provided to the randomizer 210, the randomizer 210 may generate a randomizing seed corresponding to the target memory block. That is, the randomizer 210 is configured to generate a randomizing seed corresponding to the target memory block among randomizing seeds corresponding to the plurality of memory blocks BLK1 to BLKz. Subsequently, the randomizer 210 randomizes data received from the host 300 through the generated randomizing seed, and writes the randomized data to the target memory block of the semiconductor memory device 100. As is widely known in the art, as the data operated based on the randomizing seed is written to the memory cell array 110, the threshold voltage distribution of the memory cells in the memory cell array 110 is improved, and the reliability of data stored in the memory cells is enhanced.

Furthermore, the randomizer 210 is activated in a read operation. In the read operation, the controller 200 reads data from the semiconductor memory device 100. In addition, a de-randomizing seed corresponding to a read memory block is generated. That is, if a block address of a read memory block is provided to the randomizer 210, the randomizer 210 may generate a de-randomizing seed corresponding to the read memory block. That is, the randomizer 210 is configured to generate a de-randomizing seed corresponding to the read memory block among de-randomizing seeds corresponding to the plurality of memory blocks BLK1 to BLKz.

Subsequently, the randomizer 210 may de-randomize the read data through the generated de-randomizing seed. The de-randomized data may be transmitted to the host 300.

In a typical memory system, a randomizing seed and a de-randomizing seed are generated according to a block address of a memory block as described above. Accordingly, when data having the same pattern are written with respect to the same address, the same randomizing seed is generated, and hence the randomized data are the same. This has a bad influence on the threshold voltage distribution of the memory cells in the memory cell array 110.

In the memory system 10 according to the present disclosure, data to be written is randomized according to a program-erase count value of a target memory block to which the data is to be written. Accordingly, although data having the same pattern is repeatedly written with respect to the same address, the to-be-written data can be inverted according to the program-erase count value of the target memory block. Thus, the threshold voltage distribution of the memory cells in the memory cell array 110 is improved, and the reliability of data stored in the memory cells is enhanced.

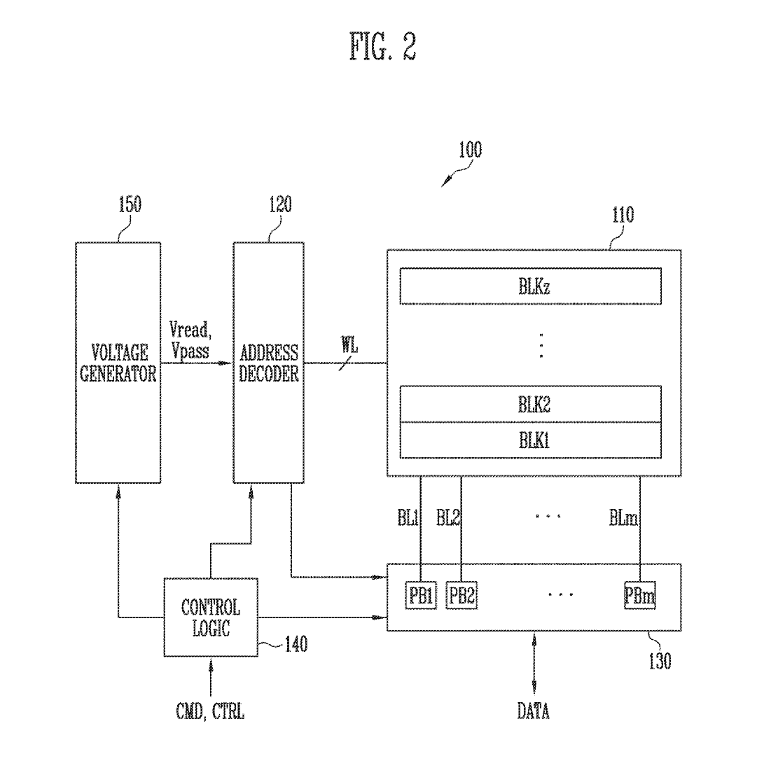

FIG. 2 is a block diagram illustrating the semiconductor memory device shown in FIG. 1.

Referring to FIG. 2, the semiconductor memory device 100 includes a memory cell array 110, an address decoder 120, a read/write circuit 130, a control logic 140, and a voltage generator 150.

The memory cell array 110 includes a plurality of memory blocks BLK1 to BLKz. The plurality of memory blocks BLK1 to BLKz are coupled to the address decoder 120 through word lines WL. The plurality of memory blocks BLK1 to BLKz are coupled to the read/write circuit 130 through bit lines BL1 to BLm. Each of the plurality of memory blocks BLK1 to BLKz includes a plurality of memory cells. In an embodiment, the plurality of memory cells are nonvolatile memory cells, and may be configured as nonvolatile memory cells having a vertical channel structure. The memory cell array 110 may be configured as a memory cell array having a two-dimensional structure. In some embodiments, the memory cell array 110 may be configured as a memory cell array having a three-dimensional structure. Each of the plurality of memory cells included in the memory cell array 110 may store data of at least one bit. In an embodiment, each of the plurality of memory cells included in the memory cell array 110 may be a single-level cell (SLC) that stores data of one bit. In another embodiment, each of the plurality of memory cells included in the memory cell array 110 may be a multi-level cell (MLC) that stores data of two bits. In still another embodiment, each of the plurality of memory cells included in the memory cell array 110 may be a triple-level cell that stores data of three bits. In still another embodiment, each of the plurality of memory cells included in the memory cell array 110 may be a quad-level cell that stores data of four bits. In some embodiments, the memory cell array 110 may include a plurality of memory cells that each stores data of five or more bits.

The address decoder 120, the read/write circuit 130, the control logic 140, and the voltage generator 150 operate as a peripheral circuit that drives the memory cell array 110. The address decoder 120 is coupled to the memory cell array 110 through the word lines WL. The address decoder 120 is configured to operate in response to the control of the control logic 140. The address decoder 120 receives an address through an input/output buffer (not shown) provided in the semiconductor memory device 100.

The address decoder 120 is configured to decode a block address in the received address. The address decoder 120 selects at least one memory block according to the decoded block address. In a read voltage application operation during a read operation, the address decoder 120 applies a read voltage Vread generated by the voltage generator 150 to a selected word line among the selected memory blocks, and applies a pass voltage Vpass to the other unselected word lines. In a program verify operation, the address decoder 120 applies a verify voltage generated by the voltage generator 150 to the selected word line among the selected memory blocks, and applies the pass voltage Vpass to the other unselected word lines.

The address decoder 120 is configured to decode a column address in the received address. The address decoder 120 transmits the decoded column address to the read/write circuit 130.

Read and program operations of the semiconductor memory device 100 are performed in units of pages. An address received in a request of the read operation and the program operation includes a block address, a row address, and a column address. The address decoder 120 selects one memory block and one word line according to the block address and the row address. The column address is decoded by the address decoder 120 to be provided to the read/write circuit 130.

The address decoder 120 may include a block decoder, a row decoder, a column decoder, an address buffer, and the like.

The read/write circuit 130 includes a plurality of page buffers PB1 to PBm. The read/write circuit 130 may operate as a “read circuit” in a read operation of the memory cell array 110, and operate as a “write circuit” in a write operation of the memory cell array 110. The plurality of page buffers PB1 to PBm are coupled to the memory cell array 110 through the bit lines BL1 to BLm. In order to sense threshold voltages of memory cells in the read operation and the program verify operation, the plurality of page buffers PB1 to PBm sense a change in amount of current flowing depending on a program state of a corresponding memory cell while continuously supplying sensing current to bit lines coupled to the memory cells, and latch the sensed change as sensing data. The read/write circuit 130 operates in response to page buffer control signals output from the control logic 140.

In the read operation, the read/write circuit 130 temporarily stores read data by sensing data of a memory cell and then outputs data DATA to the input/output buffer (not shown) of the semiconductor memory device 100. In an exemplary embodiment, the read/write circuit 130 may include a column selection circuit, and the like, in addition to the page buffers (or page registers).

The control logic 140 is coupled to the address decoder 120, the read/write circuit 130, and the voltage generator 150. The control logic 140 receives a command CMD and a control signal CTRL through the input/output buffer (not shown) of the semiconductor memory device 100. The control logic 140 is configured to control overall operations of the semiconductor memory device 100 in response to the control signal CTRL. Also, the control logic 140 outputs a control signal for controlling sensing node precharge potential levels of the plurality of page buffers PB1 to PBm. The control logic 140 may control the read/write circuit 130 to perform the read operation of the memory cell array 110.

In the read operation, the voltage generator 150 generates the read voltage Vread and the pass voltage Vpass in response to a control signal output from the control logic 140. In order to generate a plurality of voltages having various voltage levels, the voltage generator 150 may include a plurality of pumping capacitors for receiving an internal power voltage, and generate a plurality of voltages by selectively activating the plurality of pumping capacitors under the control of the control logic 140.

The address decoder 120, the read/write circuit 130, and the voltage generator 150 may serve as a “peripheral circuit” that performs a read operation, a write operation, and an erase operation on the memory cell array 110. The peripheral circuit performs the read operation, the write operation, and the erase operation on the memory cell array 110 under the control of the control logic 140.

FIG. 3 is a diagram illustrating an embodiment of the memory cell array shown in FIG. 2.

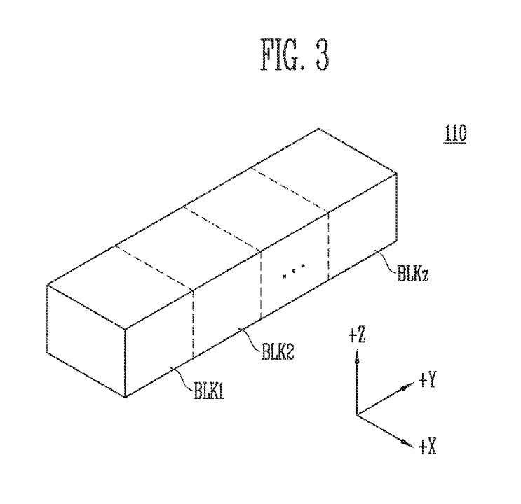

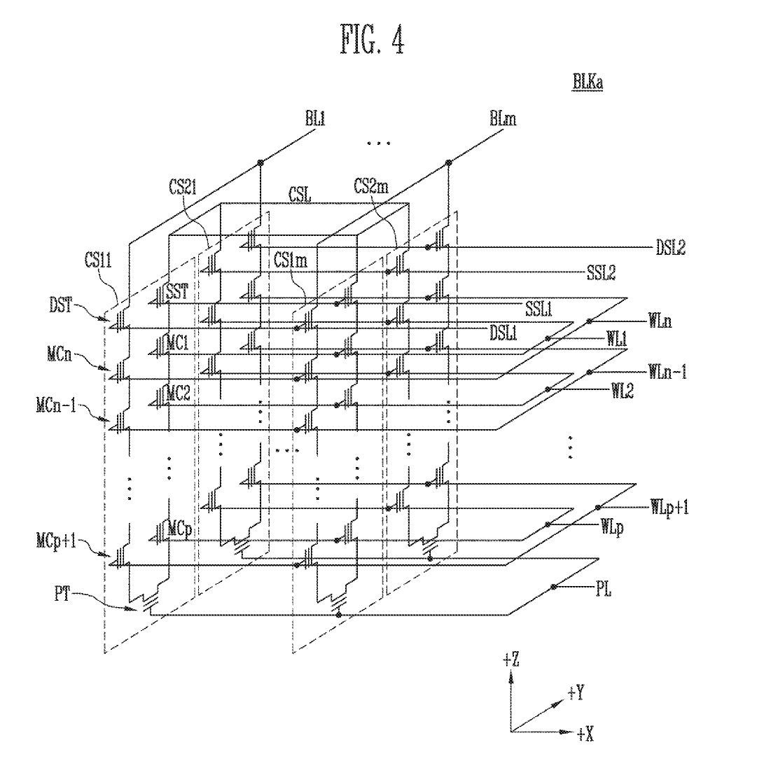

Referring to FIG. 3, the memory cell array 110 includes a plurality of memory blocks BLK1 to BLKz. Each memory block has a three-dimensional structure. Each memory block includes a plurality of memory cells stacked above a substrate. The plurality of memory cells are arranged along +X, +Y, and +Z directions. The structure of each memory block will be described in more detail with reference to FIGS. 4 and 5.

FIG. 4 is a circuit diagram illustrating any one memory block BLKa among the memory blocks BLK1 to BLKz shown in FIG. 3.

Referring to FIG. 4, the memory block BLKa includes a plurality of cell strings CS11 to CS1m and CS21 to CS2m. In an embodiment, each of the plurality of cell strings CS11 to CS1m and CS21 to CS2m may be formed in a ‘U’ shape. In the memory block BLKa, m cell strings are arranged in a row direction (i.e., a +X direction). In FIG. 4, it is illustrated that two cell strings are arranged in a column direction (i.e., a +Y direction). However, this is for convenience of description, and it will be understood that three cell strings may be arranged in the column direction.

Each of the plurality of cell strings CS11 to CS1m and CS21 to CS2m includes at least one source select transistor SST, first to nth memory cells MC1 to MCn, a pipe transistor PT, and at least one drain select transistor DST.

The select transistors SST and DST and the memory cells MC1 to MCn may have structures similar to one another. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and memory cells MC1 to MCp.

In an embodiment, the source select transistors of cell strings arranged on the same row are coupled to a source select line extending in the row direction, and the source select transistors of cell strings arranged on different rows are coupled to different source select lines. In FIG. 4, the source select transistors of the cell strings CS11 to CS1m on a first row are coupled to a first source select line SSL1. The source select transistors of the cell strings CS21 to CS2m on a second row are coupled to a second source select line SSL2.

In an embodiment, the source select transistors of the cell strings CS11 to CS1m and CS21 to CS2m may be commonly coupled to one source select line.

The first to nth memory cells MC1 to MCn of each cell string are coupled between the source select transistor SST and the drain select transistor DST.

The first to nth memory cells MC1 to MCn may be divided into first to pth memory cells MC1 to MCp and a (p+1)th to nth memory cells MCp+1 to MCn. The first to pth memory cells MC1 to MCp are sequentially arranged in the opposite direction of a +Z direction, and are coupled in series between the source select transistor SST and the pipe transistor PT. The (p+1)th to nth memory cells MCp+1 to MCn are sequentially arranged in the +Z direction, and are coupled in series between the pipe transistor PT and the drain select transistor DST. The first to pth memory cells MC1 to MCp and the (p+1)th to nth memory cells MCp+1 to MCn are coupled through the pipe transistor PT. Gate electrodes of the first to nth memory cells MC1 to MCn of each cell string are coupled to first to nth word lines WL1 to WLn, respectively.

A gate of the pipe transistor PT of each cell string is coupled to a pipe line PL.

The drain select transistor DST of each cell string is coupled between a corresponding bit line and the memory cells MCp+1 to MCn. Cell strings arranged in the row direction are coupled to a drain select line extending in the row direction. The drain select transistors of the cell strings CS11 to CS1m on the first row are coupled to a first drain select line DSL1. The drain select transistors of the cell strings CS21 to CS2m on the second row are coupled to a second drain select line DSL2.

Cell strings arranged in the column direction are coupled to a bit line extending in the column direction. In FIG. 4, the cell strings CS11 and CS21 on a first column are coupled to a first bit line BL1. The cell strings CS1m and CS2m on an mth column are coupled to an mth bit line BLm.

Memory cells coupled to the same word line in the cell strings arranged in the row direction constitute one page. For example, memory cells coupled to the first word line WL1 in the cell strings CS11 to CS1m on the first row constitute one page. Memory cells coupled to the first word line WL1 in the cell strings CS21 to CS2m on the second row constitute another page. As any one of the drain select lines DSL1 and DSL2 is selected, cell strings arranged in one row direction may be selected. As any one of the word lines WL1 to WLn is selected, one page may be selected in the selected cell strings.

In an embodiment, even bit lines and odd bit lines may be provided instead of the first to mth bit lines BL1 to BLm. In addition, even-numbered cell strings among the cell strings CS11 to CS1m or CS21 to CS2m arranged in the row direction may be coupled to the even bit lines, respectively, and odd-numbered cell strings among the cell strings CS11 to CS1m or CS21 to CS2m arranged in the row direction may be coupled to the odd bit lines, respectively.

In an embodiment, at least one of the first to nth memory cells MC1 to MCn may be used as a dummy memory cell. For example, the at least one dummy memory cell may be provided to decrease an electric field between the source select transistor SST and the memory cells MC1 to MCp. Alternatively, the at least one dummy memory cell may be provided to decrease an electric field between the drain select transistor DST and the memory cells MCp+1 to MCn. As a larger number of dummy memory cells are provided, the reliability of an operation of the memory block BLKa is improved. On the other hand, the size of the memory block BLKa is increased. As a smaller number of dummy memory cells are provided, the size of the memory block BLKa Is decreased. On the other hand, the reliability of an operation of the memory block BLKa may be deteriorated.

In order to efficiently control the at least one dummy memory cell, the dummy memory cells may have a required threshold voltage. Before or after an erase operation of the memory block BLKa, a program operation may be performed on all or some of the dummy memory cells. When an erase operation is performed after the program operation is performed, the threshold voltage of the dummy memory cells control a voltage applied to the dummy word lines coupled to the respective dummy memory cells, so that the dummy memory cells can have the required threshold voltage.

FIG. 5 is a circuit diagram illustrating an embodiment BLKb of the one memory block among the memory blocks BLK1 to BLKz shown in FIG. 3.

Referring to FIG. 5, the memory block BLKb includes a plurality of cell strings CS11′ to CS1m′ and CS21′ to CS2m′. Each of the plurality of cell strings CS11′ to CS1m′ and CS21′ to CS2m′ extends along the +Z direction. Each of the plurality of cell strings CS11′ to CS1m′ and CS21′ to CS2m′ includes at least one source select transistor SST, first to nth memory cells MC1 to MCn, and at least one drain select transistor DST, which are stacked on a substrate (not shown) under the memory block BLKb.

The source select transistor SST of each cell string is coupled between a common source line CSL and the memory cells MC1 to MCn. The source select transistors of cell strings arranged on the same row are coupled to the same source select line. The source select transistors of the cell strings CS11′ to CS1m′ arranged on a first row are coupled to a first source select line SSL1. Source select transistors of the cell strings CS21′ to CS2m′ arranged on a second row are coupled to a second source select line SSL2. In another embodiment, the source select transistors of the cell strings CS11′ to CS1m′ and CS21′ to CS2m′ may be commonly coupled to one source select line.

The first to nth memory cells MC1 to MCn of each cell string are coupled in series between the source select transistor SST and the drain select transistor DST. Gate electrodes of the first to nth memory cells MC1 to MCn are coupled to first to nth word lines WL1 to WLn, respectively.

The drain select transistor DST of each cell string is coupled between a corresponding bit line and the memory cells MC1 to MCn. The drain select transistors of cell strings arranged in the row direction are coupled to a drain select line extending in the row direction. The drain select transistors of the cell strings CS11′ to CS1m′ on the first row are coupled to a first drain select line DSL1. The drain select transistors of the cell strings CS21′ to CS2m′ on the second row are coupled to a second drain select line DSL2.

Consequently, the memory block BLKb of FIG. 5 has an equivalent circuit similar to that of the memory block BLKa of FIG. 4, except that the pipe transistor PT is excluded from each cell string.

In an embodiment, even bit lines and odd bit lines may be provided instead of the first to mth bit lines BL1 to BLm. In addition, even-numbered cell strings among the cell strings CS11′ to CS1m′ or CS21′ to CS2m′ arranged in the row direction may be coupled to the even bit lines, respectively, and odd-numbered cell strings among the cell strings CS11′ to CS1m′ or CS21′ to CS2m′ arranged in the row direction may be coupled to the odd bit lines, respectively.

In an embodiment, at least one of the first to nth memory cells MC1 to MCn may be used as a dummy memory cell. For example, the at least one dummy memory cell may be provided to decrease an electric field between the source select transistor SST and the memory cells MC1 to MCp. Alternatively, the at least one dummy memory cell may be provided to decrease an electric field between the drain select transistor DST and the memory cells MCp+1 to MCn. As a larger number of dummy memory cells are provided, the reliability of an operation of the memory block BLKb is improved. On the other hand, the size of the memory block BLKb is increased. As a smaller number of dummy memory cells are provided, the size of the memory block BLKb is decreased. On the other hand, the reliability of an operation of the memory block BLKb may be deteriorated.

In order to efficiently control the at least one dummy memory cell, the dummy memory cells may have a required threshold voltage. Before or after an erase operation of the memory block BLKb, a program operation may be performed on all or some of the dummy memory cells. When an erase operation is performed after the program operation is performed, the threshold voltage of the dummy memory cells control a voltage applied to the dummy word lines coupled to the respective dummy memory cells, so that the dummy memory cells can have the required threshold voltage.

FIG. 6 is a circuit diagram illustrating an embodiment BLKc of the one memory block among a plurality of memory blocks BLK1 to BLKz included in the memory cell array 110 shown in FIG. 2.

Referring to FIG. 6, the memory block BLKc includes a plurality of strings CS1 to CSm. The plurality of strings CS1 to CSm may be coupled to a plurality of bit lines BL1 to BLm, respectively. Each of the plurality of strings CS1 to CSm includes at least one source select transistor SST, first to nth memory cells MC1 to MCn, and at least one drain select transistor DST.

Each of the select transistors SST and DST and the memory cells MC1 to MCn may have a similar structure. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and the memory cells MC1 to MCn.

The first to nth memory cells MC1 to MCn of each cell string is coupled between the source select transistor SST and the drain select transistor DST.

The drain select transistor DST of each cell string is coupled between a corresponding bit line and the memory cells MC1 to MCn.

Memory cells coupled to the same word line constitute one page. As a drain select line DSL is selected, the cell strings CS1 to CSm may be selected. As any one of word lines WL1 to WLn is selected, one page among selected cell strings may be selected.

In another embodiment, even bit lines and odd bit lines may be provided instead of the first to mth bit lines BL1 to BLm. Even-numbered cell strings among the cell strings CS1 to CSm may be coupled to the even bit lines, respectively, and odd-numbered cell strings among the cell strings CS1 to CSm may be coupled to the odd bit lines, respectively.

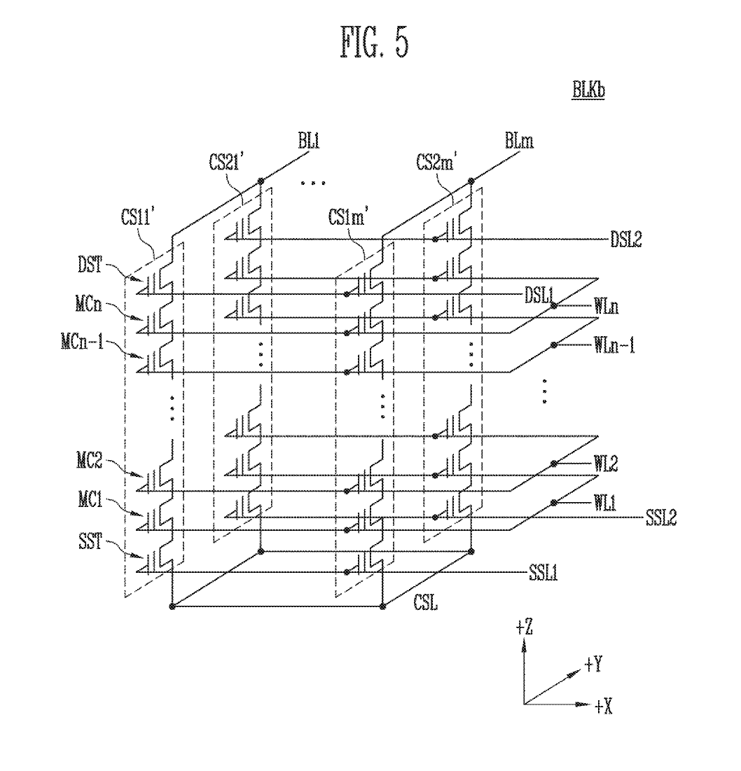

FIG. 7 is a block diagram illustrating an operation of the randomizer 210 shown in FIG. 1.

Referring to FIG. 7, input/output data of the randomizer 210 shown in FIG. 1 are illustrated. The randomizer 210 generates randomized data, based on a block address of a target memory block to which data is to be written and a program-erase count value. Specifically, the randomizer 210 receives original data DATA_OGN transferred from the host 300, and receives a program-erase count value PE_CNT of the target memory block. Also, the randomizer 210 may generate a randomizing seed, based on a block address of the target memory block. Furthermore, the randomizer 210 generates randomized data DATA_RND, based on the original data DATA_OGN and the program-erase count value PE_CNT. The randomized data DATA_RND may be written into the target memory block corresponding to the block address.

In accordance with the embodiment of the present disclosure, the randomizer 210 generates the randomized data DATA_RND, using the program-erase count value PE_CNT of the target memory block, in addition to a randomizing seed corresponding to the block address of the target memory block. Whenever an erase operation is performed on a memory block, the program-erase count value PE_CNT of the corresponding memory block is changed. Accordingly, although data having the same pattern is repeatedly written with respect to the same address, the randomized data DATA_RND may be changed depending on the program-erase count value of the target memory block. Thus, the threshold voltage distribution of the memory cells in the memory cell array 110 is improved, and the reliability of data stored in the memory cells is enhanced.

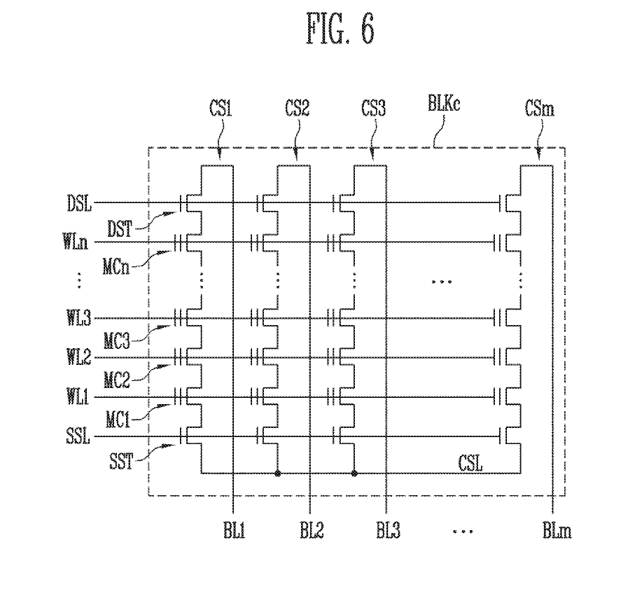

FIG. 8 is a block diagram illustrating an exemplary embodiment of the randomizer of FIG. 7.

Referring to FIG. 8, the randomizer 210 includes a first randomizing circuit 310 and a second randomizing circuit 330. The first randomizing circuit 310 receives original data DATA_OGN from the host. Also, the first randomizing circuit 310 receives a seed SEED internally generated in the randomizer 210. The seed SEED corresponds to a block address of a target memory block. The first randomizing circuit 310 may generate temporary data DATA_1, based on the seed SEED and the original data DATA_OGN. The temporary data DATA_1 may be data generated as a result obtained by randomizing the original data DATA_OGN, based on the seed SEED.

The second randomizing circuit 330 receives the temporary data DATA_1 and a program-erase count value PE_CNT of the target memory block. The second randomizing circuit 330 converts the temporary data DATA_1 into randomized data DATA_RND, based on the program-erase count value PE_CNT. Therefore, when the program-erase count value PE_CNT is changed, different randomized data DATA_RND may be generated even with respect to the same temporary data DATA_1. As an example, the second randomizing circuit 330, based on the program-erase count value PE_CNT, may output the temporary data DATA_1 as the randomized data DATA_RND, or invert the temporary data DATA_1 and output the inverted result as the randomized data DATA_RND. An exemplary embodiment of the second randomizing circuit 330 will be described later with reference to FIG. 9.

FIG. 9 is a block diagram illustrating an exemplary embodiment of the second randomizing circuit 330 shown in FIG. 8.

Referring to FIG. 9, the second randomizing circuit 330 may include an inverter 331 and a multiplexer 333. The inverter 331 inverts the temporary data DATA_1 and outputs the inverted result as inverted temporary data INV_DATA_1. The multiplexer 333 receives the temporary data DATA_1 and the inverted temporary data INV_DATA_1. The multiplexer 333 may output any one of the temporary data DATA_1 and the inverted temporary data INV_DATA_1 as randomized data DATA_RND, based on the program-erase count value PE_CNT of the target memory block.

According to the present disclosure, the program-erase count value PE_CNT of the target memory block may be a numeral indicating how many times the target memory block has been totally erased. In an exemplary embodiment, the program-erase count value PE_CNT may be configured as data of one bit. In this case, the program-erase count value PE_CNT of the target memory block may represent the program-erase count of the target memory block as even (e.g., when the bit value is even or zero) or as odd (e.g., when the bit value is odd or one).

In an exemplary embodiment, when the program-erase count value PE_CNT is even, the multiplexer 333 may output the temporary data DATA_1 as the randomized data DATA_RND. When the program-erase count value PE_CNT is odd, the multiplexer 333 may output the inverted temporary data INT_DATA_1 as the randomized data DATA_RND.

In another embodiment, when the program-erase count value PE_CNT is odd, the multiplexer 333 may output the temporary data DATA_1 as the randomized data DATA_RND. When the program-erase count value PE_CNT is even, the multiplexer 333 may output the inverted temporary data INT_DATA_1 as the randomized data DATA_RND.

Accordingly, the program-erase count value PE_CNT is changed, the randomized temporary data DATA_1 is output as the randomized data DATA_RND, or the inverted temporary data INV_DATA_1 is output as the randomized data DATA_RND. Thus, although data having the same pattern is repeatedly written with respect to the same address, data can be inverted to be written according to the program-erase count value of the corresponding memory block. Accordingly, the threshold voltage distribution of the memory cells in the memory cell array 110 is improved, and the reliability of data stored in the memory cells is enhanced.

The configuration of the second randomizing circuit 330 shown in FIG. 9 is merely illustrative, and the present disclosure is not limited thereto. That is, it will be understood that other various configurations of the second randomizing circuit 330 are possible to generate the changed randomized data DATA_RND depending on the program-erase count value PE_CNT.

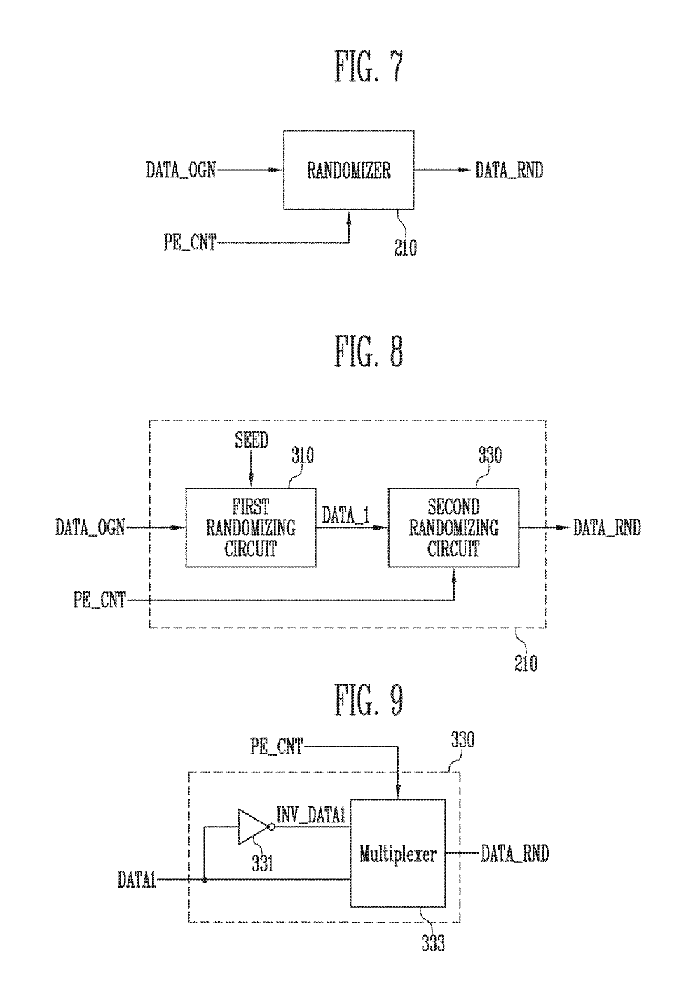

FIG. 10 is a block diagram illustrating an exemplary embodiment of the randomizer 210 shown in FIG. 7.

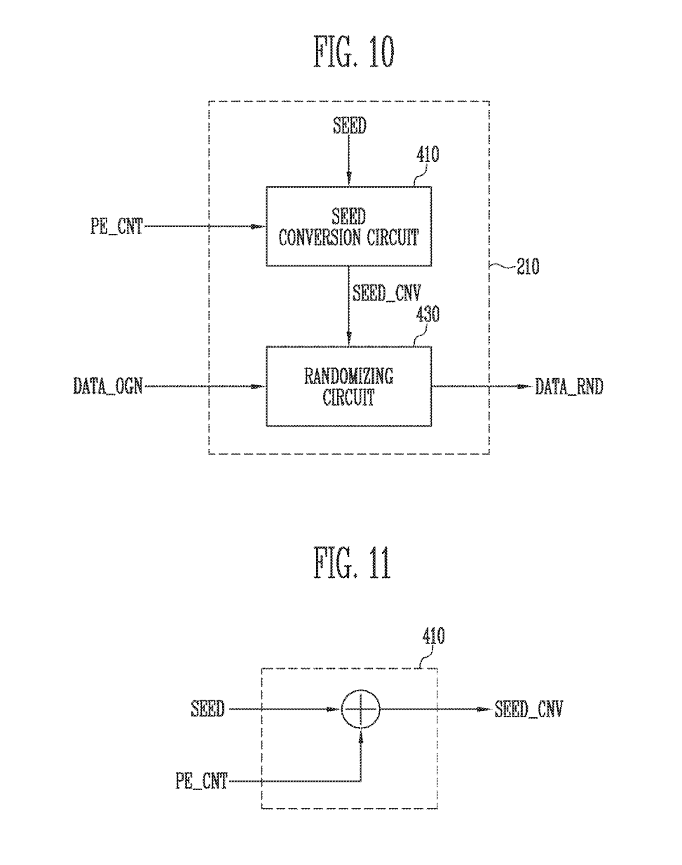

Referring to FIG. 10, the randomizer may include a seed conversion circuit 410 and a randomizing circuit 430. The seed conversion circuit 410 may convert the randomizing seed SEED corresponding to the block address of the target memory block, based on the program-erase count value PE_CNT of the target memory block, and output the converted result as a conversion seed SEED_CNV. The randomizing circuit 430 may generate the randomized data DATA_RND by receiving original data DATA_OGN from the host 300 and the conversion seed SEED_CNV from the seed conversion circuit 410. Since the conversion seed SEED_CNV is generated based on the program-erase count value PE_CNT, the conversion seed SEED_CNV is changed as the program-erase count value PE_CNT is changed. Consequently, the randomized data DATA_RND is also changed as the conversion seed SEED_CNV is changed. Thus, although data having the same pattern is repeatedly written with respect to the same address, data can be inverted to be written according to the program-erase count value of the corresponding memory block. Accordingly, the threshold voltage distribution of the memory cells in the memory cell array 110 is improved, and the reliability of data stored in the memory cells is enhanced. An exemplary embodiment of the seed conversion circuit 410 will be described later with reference to FIG. 11.

FIG. 11 is a block diagram illustrating an exemplary embodiment of the seed conversion circuit 410 of FIG. 10.

Referring to FIG. 11, the seed conversion circuit 410 may be configured with an adder. A conversion seed SEED_CNV may be generated through an add operation to the program-erase count value PE_CNT corresponding to the target memory block and the seed SEED. Thus, the conversion seed SEED_CNV is changed as the program-erase count value PE_CNT is changed.

The configuration of the seed conversion circuit 410 shown in FIG. 11 is merely illustrative, and the present disclosure is not limited thereto. That is, it will be understood that other various configurations of the seed conversion circuit 410 are possible to generate the conversion seed SEED_CNV changed as the program-erase count value PE_CNT is changed.

Referring to FIGS. 7 to 11, a case in which the memory controller 200 randomizes data, based on a program-erase count value, is described. In this case, the semiconductor memory device 100 writes the randomized data received from the memory controller 200 to a target memory block.

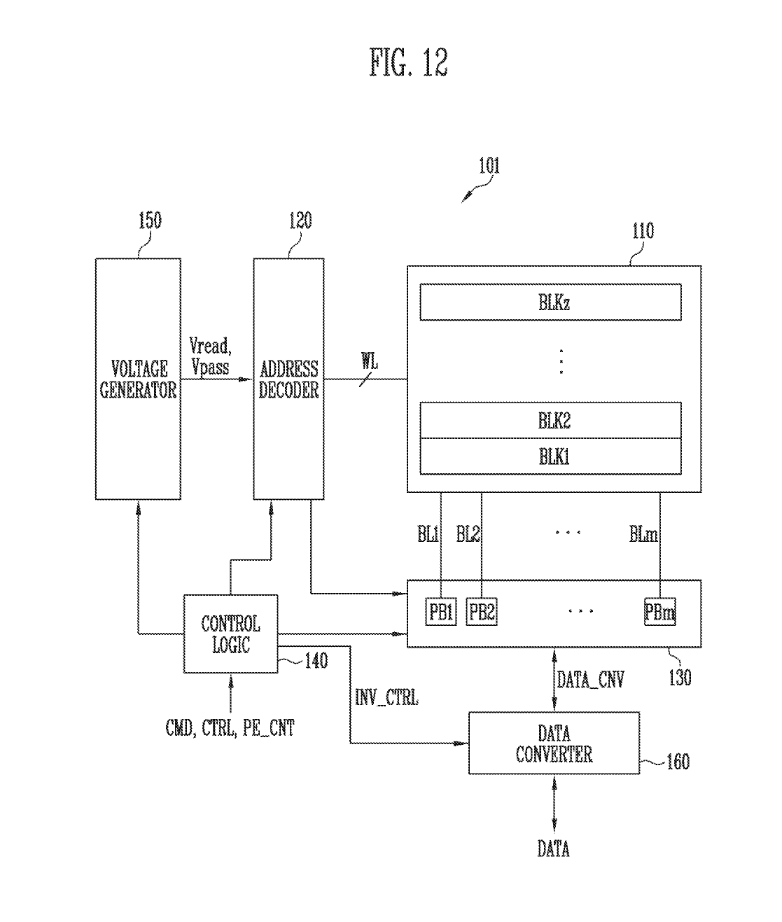

Hereinafter, a case in which the controller 200 preliminarily randomizes data and the semiconductor memory device 100 converts the preliminarily randomized data to generate a randomized data to be written into a target memory block according to a program-erase count value will be described with reference to FIGS. 12 and 13. In this case, the randomizer 210 of the controller 200 may include the first randomizing circuit 310 without the second randomizing circuit 330, and may output not the randomized data DATA_RND but the temporary data DATA_1, as described with reference to FIG. 8.

FIG. 12 is a block diagram illustrating an exemplary embodiment of the semiconductor memory device in accordance with the embodiment of the present disclosure.

Referring to FIG. 12, the semiconductor memory device 101 includes the memory cell array 110, the address decoder 120, the read/write circuit 130, the control logic 140, and the voltage generator 150. The semiconductor memory device 101 of FIG. 12 is different from the semiconductor memory device 100 of FIG. 2 in that the semiconductor memory device 101 of FIG. 12 further includes a data converter 160. The data converter 160 may correspond to the second randomizing circuit 330 as described with reference to FIG. 8. Among the components of the semiconductor memory device 101 of FIG. 12, descriptions of components identical to those of the semiconductor memory device 100 of FIG. 2 will be omitted to avoid redundancy.

In FIG. 12, the control logic 140 receives a program-erase count value PE_CNT of a target memory block. The control logic 140 generates a conversion control signal CNV_CTRL, based on the program-erase count value PE_CNT, and transfers the generated conversion control signal CNV_CTRL to the data converter 160. As an example, the control logic 140 may transfer the program-erase count value PE_CNT as the conversion control signal CNV_CTRL to the data converter 160.

The data converter 160 receives data DATA from the controller 200. The data DATA may correspond to the temporary data DATA_1 described with reference to FIG. 8. The data converter 160 converts data DATA, based on the conversion control signal CNV_CTRL, and transfers the converted data DATA_CNV to the read/write circuit 130. The converted data DATA_CNV may correspond to the randomized data DATA_RND described with reference to FIG. 8. According to a value of the conversion control signal CNV_CTRL, the data converter 160 may transfer the received data DATA as the inverted data DATA_CNV to the read/write circuit 130 without any conversion of the received data DATA, or invert the received data DATA and transfer the inverted data DATA_CNV to the read/write circuit 130. The read/write circuit 130 writes the received data DATA or the conversion data DATA_CNV to the target memory block. An exemplary embodiment of the data converter 160 will be described later with reference to FIG. 13.

FIG. 13 is a block diagram illustrating an exemplary embodiment of the data converter shown in FIG. 12.

The data converter 160 may include an inverter 510 and a multiplexer 530. The inverter 510 may invert received data DATA and output the inverted result as inverted data INV_DATA. The multiplexer 530 may receive the data DATA and the inverted data INV_DATA, and output any one of the data DATA and the inverted data INV_DATA as conversion data DATA_CNV, based on a conversion control signal CNV_CTRL.

Referring together to FIGS. 12 and 13, the data DATA input to the data converter 160 is data preliminarily randomized by the memory controller 200. In the embodiment, the memory controller 200 may preliminarily randomize data, based on only a randomizing seed SEED corresponding to a block address of a target memory block, regardless of the program-erase count value PE_CNT of the target memory block. Therefore, the data converter 160 of the semiconductor memory device 101, based on the program-erase count value PE_CNT, may transfer the preliminarily randomized data DATA to the read/write circuit 130, or invert the preliminarily randomized data DATA and transfer the inverted data DATA_INV to the read/write circuit 130. Thus, although data having the same pattern is repeatedly written with respect to the same address, data can be inverted to be written according to the program-erase count value of the target memory block. Accordingly, the threshold voltage distribution of the memory cells in the memory cell array 110 is improved, and the reliability of data stored in the memory cells is enhanced.

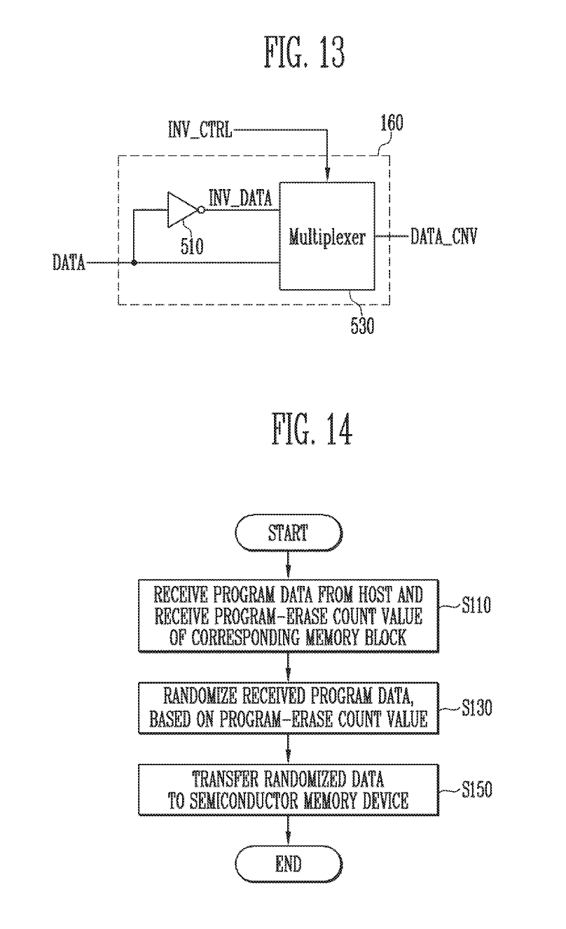

FIG. 14 is a flowchart illustrating an operating method for a memory controller in accordance with an embodiment of the present disclosure.

Referring to FIG. 14, the operating method of the memory controller according to the embodiment of the present disclosure includes a step S110 of receiving program data from the host and receiving a program-erase count value PE_CNT of a target memory block, a step S130 of randomizing the received program data, based on the program-erase count value PE_CNT of the target memory block, and a step S150 of transferring the randomized data to the semiconductor memory device 100. Referring to FIG. 7, it can be seen that the steps S110, S130, and S150 may be performed by the randomizer 210. The step S130 of FIG. 14 will be described in more detail with reference to FIG. 15.

FIG. 15 is a flowchart illustrating in more detail an embodiment of the step S130 of randomizing the program data, shown in FIG. 14.

Referring to FIG. 15, the step S130 of randomizing the program data includes a step S210 of generating first randomized data by randomizing the received program data, a step S230 of determining whether the program-erase count value PE_CNT is even, and a step S250 of inverting the first randomized data when the program-erase count value PE_CNT is even. Referring together to FIGS. 8, 9, and 15, the step S210 of generating the first randomized data may be performed by the first randomizing circuit 310. Here, the first randomized data corresponds to the temporary data DATA_1 of FIG. 8. Moreover, the step S230 of determining whether the program-erase count value PE_CNT is even and the step S250 of inverting the first randomized data when the program-erase count value PE_CNT is even may be performed by the second randomizing circuit 330.

A case in which the first randomized data is inverted when the program-erase count value PE_CNT is even is illustrated in FIG. 15. However, this is merely illustrative. In another embodiment, it will be apparent that the first randomized data may be inverted when the program-erase count value PE_CNT is odd.

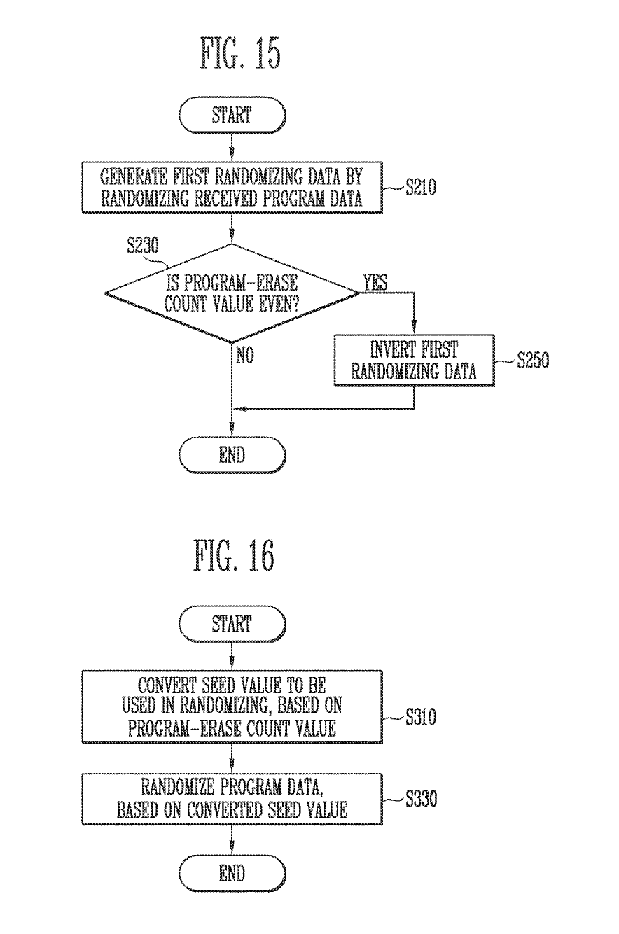

FIG. 16 is a flowchart illustrating in more detail another embodiment of the step S130 of randomizing the program data, shown in FIG. 14.

Referring to FIG. 16, the step S130 of randomizing the program data includes a step S310 of converting a seed value corresponding to the target memory block, based on the program-erase count value PE_CNT of the target memory block and a step S330 of randomizing the program data, based on the converted seed value. Referring together to FIGS. 10 and 16, it can be seen that the step S310 may be performed by the seed conversion circuit 410 and the step S330 may be performed by the randomizing circuit 430. In the step S310, the conversion seed SEED_CNV may be generated by adding the program-erase count value PE_CNT to the seed SEED as described above.

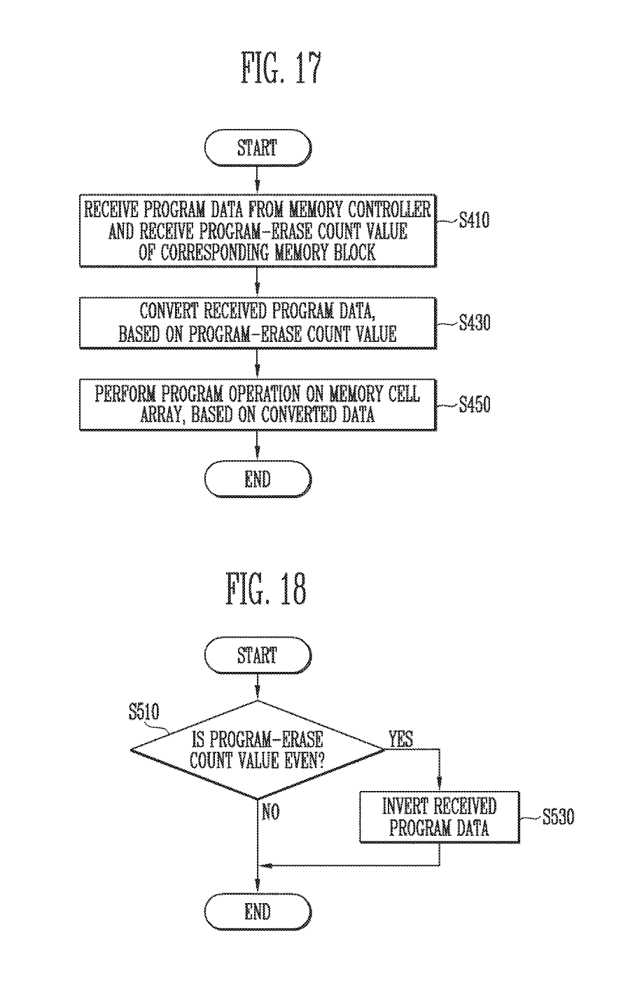

FIG. 17 is a flowchart illustrating an operating method for the semiconductor memory device 101 of FIG. 12 in accordance with an embodiment of the present disclosure.

The operating method for the semiconductor memory device 101 of FIG. 12 according to the embodiment of the present disclosure includes a step S410 of receiving program data from the memory controller and receiving a program-erase count value PE_CNT of a target memory block, a step S430 of converting the received program data, based on the program-erase count value PE_CNT, and a step S450 of performing a program operation on the memory cell array 110, based on the converted data. Referring together to FIGS. 12 and 17, it can be seen that, the step S410 may be performed by the control logic 140, the step S430 may be performed by the data converter 160, and the step S450 may be performed by a peripheral circuit. Here, the peripheral circuit may be configured to include the address decoder 120, the read/write circuit 130, and the voltage generator 150.

FIG. 18 is a flowchart illustrating in more detail an embodiment of the step of converting the program data, shown in FIG. 17.

Referring to FIG. 18, the step S130 of converting the program data includes a step S510 of determining whether the program-erase count value of the target memory block is even and a step S530 of inverting the received program data when the program-erase count value is even. Referring together to FIGS. 12, 13, and 18, it can be seen that the step S510 of determining whether the program-erase count value is even may be performed by the control logic 140. In addition, it can be seen that the step S530 of inverting the received program data when the program-erase count value is even may be performed by the data converter 160.

A case in which the program data is inverted when the program-erase count value is even is illustrated in FIG. 18. However, this is merely illustrative. In another embodiment, it will be apparent that the program data may be inverted when the program-erase count value PE_CNT is odd.

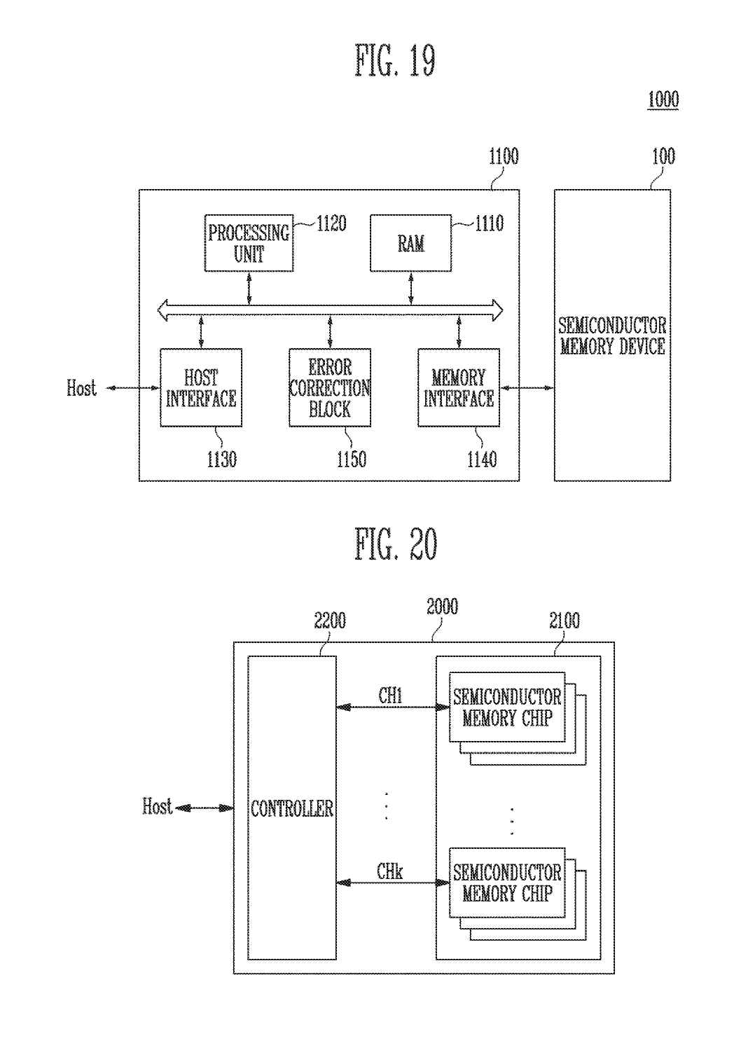

FIG. 19 is a block diagram illustrating an embodiment 1000 of the memory system shown in FIG. 1.

Referring to FIG. 19, the memory system 1000 includes a semiconductor memory device 100 and the controller 1100. The semiconductor memory device 100 may be the semiconductor memory device described with reference to FIG. 1. Hereinafter, overlapping descriptions will be omitted. Alternatively, the semiconductor memory device 101 shown in FIG. 12 may be included in substitution for the semiconductor memory device 100.

The controller 1100 is coupled to a host Host and the semiconductor memory device 100. The controller 1100 corresponds to the memory controller 200. The controller 1100 is configured to access the semiconductor memory device 100 in response to a request from the host Host. For example, the controller 1100 is configured to control read, write, erase, and background operations of the semiconductor memory device 100. The controller 1100 is configured to provide an interface between the semiconductor memory device 100 and the host Host. The controller 1100 is configured to drive firmware for controlling the semiconductor memory device 100.

The controller 1100 includes a random access memory (RAM) 1110, a processing unit 1120, a host interface 1130, a memory interface 1140, and an error correction block 1150. The RAM 1110 is used as at least one of an operation memory of the processing unit 1120, a cache memory between the semiconductor memory device 100 and the host Host, and a buffer memory between the semiconductor memory device 100 and the host Host. The processing unit 1120 controls overall operations of the controller 1100. Also, the controller 1100 may arbitrarily store program data provided from the host Host in a write operation.

The host interface 1130 includes a protocol for exchanging data between the host Host and the controller 1100. In an exemplary embodiment, the controller 1100 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol.

The memory interface 1140 interfaces with the semiconductor memory device 100. For example, the memory interface 1140 may include a NAND interface or a NOR interface.

The error correction block 1150 is configured to detect and correct an error of data received from the semiconductor memory device 100 by using an error correction code (ECC). The processing unit 1120 may control the semiconductor memory device 100 to adjust a read voltage, based on an error detection result of the error correction block 1150, and to perform re-reading. In an exemplary embodiment, the error correction block 1150 may be provided as a component of the controller 1100.

The controller 1100 and the semiconductor memory device 100 may be integrated into one semiconductor device. In an exemplary embodiment, the controller 1100 and the semiconductor memory device 100 may be integrated into one semiconductor device, to constitute a memory card. For example, the controller 1100 and the semiconductor memory device 100 may be integrated into one semiconductor device, to constitute a memory card such as a PC card (personal computer memory card international association (PCMCIA)), a compact flash (CF) card, a smart media card (SM or SMC), a memory stick, a multimedia card (MMC, RS-MMC or MMCmicro), an SD card (SD, miniSD, microSD or SDHC), or a universal flash storage (UFS).

The controller 1100 and the semiconductor memory device 100 may be integrated into one semiconductor device to constitute a semiconductor drive (solid state drive (SSD)). The semiconductor drive SSD includes a storage device configured to store data in a semiconductor memory. If the memory system 1000 is used as the semiconductor drive SSD, the operating speed of the host Host coupled to the memory system 1000 can be remarkably improved.

As an example, the memory system 1000 may be provided as one of various components of an electronic device such as a computer, a ultra mobile PC (UMPC), a workstation, a net-book, a personal digital assistant (PDA), a portable computer, a web tablet, a wireless phone, a mobile phone, a smart phone, an e-book, a portable multimedia player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

In an exemplary embodiment, the semiconductor memory device 100 or the memory system 1000 may be packaged in various forms. For example, the semiconductor memory device 100 or the memory system 1000 may be packaged in a manner such as package on package (PoP), ball grid arrays (BGAs), chip scale packages (CSPs), plastic leaded chip carrier (PLCC), plastic dual in-line package (PDIP), die in Waffle pack, die in wafer form, chip on board (COB), ceramic dual in-line package (CERDIP), plastic metric quad flat pack (MQFP), thin quad flat pack (TQFP), small outline integrated circuit (SOIC), shrink small out line package (SSOP), thin small outline package (TSOP), thin quad flat pack (TQFP), system in package (SIP), multi chip package (MCP), wafer-level fabricated package (WFP), or wafer-level processed stack package (WSP).

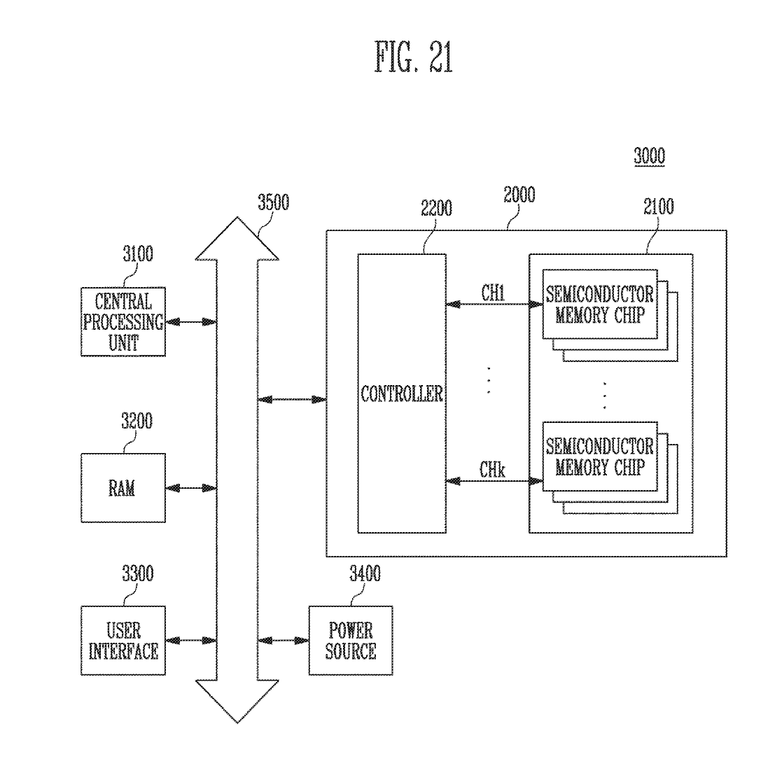

FIG. 20 is a block diagram illustrating an application example of the memory system shown in FIG. 19.

Referring to FIG. 20, the memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 20, it is illustrated that the plurality of groups communicate with the controller 2200 through first to kth channels CH1 to CHk. Each semiconductor memory chip may be configured and operated identically to the semiconductor memory device 100 or 101 described with reference to FIG. 1 or 12.

Each group is configured to communicate with the controller 2200 through one common channel. The controller 2200 is configured similarly to the controller 1100 described with reference to FIG. 19. The controller 2200 is configured to control the plurality of memory chips of the semiconductor memory device 2100 through the plurality of channels CH1 to CHk.

FIG. 21 is a block diagram illustrating a computing system including the memory system described with reference to FIG. 20.

Referring to FIG. 21, the computing system 300 includes a central processing unit 3100, a RAM 3200, a user interface 3300, a power source 3400, a system bus 3500, and a memory system 2000.

The memory system 2000 is electrically coupled to the central processing unit 3100, the RAM 3200, the user interface 3300, and the power source 3400 through the system bus 3500. Data supplied through user interface 3300 or data processed by the central processing unit 3100 are stored in the memory system 2000.

In FIG. 21, it is illustrated that the semiconductor memory device 2100 is coupled to the system bus 3500 through the controller 2200. However, the semiconductor memory device 2100 may be directly coupled to the system bus 3500. In this case, the function of the controller 2200 may be performed by the central processing unit 3100 and the RAM 3200.

In FIG. 21, it is illustrated that the memory system 2000 described with reference to FIG. 20 is provided. However, the memory system 2000 may be replaced by the memory system 1000 described with reference to FIG. 19. In an exemplary embodiment, the computing system 3000 may be configured to include both the memory systems 1000 and 2000 described with reference to FIGS. 19 and 20.

According to the present disclosure, it is possible to provide a controller having improved performance, a semiconductor memory device, and a memory system having the same.

Example embodiments have been disclosed herein, and although specific terms are employed, the terms are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A controller for controlling an operation of a semiconductor memory device including a plurality memory blocks, the controller comprising a randomizer,
wherein the randomizer generates randomized data, based on a block address of a target memory block, and a program-erase count value of the target memory block.

2. The controller of claim 1, wherein the randomizer includes:
a first randomizing circuit configured to receive original data from a host, receive a randomizing seed corresponding to the block address, and generate temporary data; and
a second randomizing circuit configured to receive the temporary data and the program-erase count value, and generate the randomized data.

3. The controller of claim 2, wherein the first randomizing circuit generates the temporary data by performing an operation on the randomizing seed and the original data.

4. The controller of claim 2, wherein the second randomizing circuit inverts the temporary data, based on the program-erase count value, and outputs the inverted result as the randomized data.

5. The controller of claim 4, wherein the second randomizing circuit includes:
an inverter configured to invert the temporary data and output the inverted result as inverted temporary data; and
a multiplexer configured to receive the temporary data and the inverted temporary data, and output any one of the temporary data and the inverted temporary data as the randomized data, based on the program-erase count value.

6. The controller of claim 1, wherein the randomizer includes:
a seed conversion circuit configured to convert a randomizing seed corresponding to the block address, based on the program-erase count value, and output the converted randomizing seed as a conversion seed; and
a randomizing circuit configured to receive original data from a host, receive the conversion seed from the seed conversion circuit, and generate the randomized data.

7. The controller of claim 6, wherein the seed conversion circuit adds the program-erase count value to the randomizing seed, and outputs the added result as the conversion seed.

8. The controller of claim 6, wherein the randomizing circuit performs an operation on the conversion seed and the original data, and outputs the operated result as the randomized data.

9. A semiconductor memory device comprising:
a memory cell array including a plurality of memory blocks having a plurality of memory cells programmed to have any one program state among a plurality of program states distinguished from each other based on threshold voltages;
a peripheral circuit configured to perform a program operation including a program voltage applying operation and a verify operation on the plurality of memory cells;
a control logic configured to control an operation of the peripheral circuit; and
a data converter configured to convert data received from a controller, based on the control of the control logic,
wherein the control logic determines whether the received data is to be converted based on a program-erase count value of a memory block to which received data is to be written.

10. The semiconductor memory device of claim 9, wherein the data converter inverts received data, based on the determination of the control logic, and outputs the inverted data to the peripheral circuit.

11. The semiconductor memory device of claim 10, wherein the control logic generates a conversion control signal, based on the program-erase count value.

12. The semiconductor memory device of claim 11, wherein the data converter includes:
an inverter configured to invert received data and output the inverted result as inverted data; and
a multiplexer configured to receive the received data and the inverted data, and output any one of the received data and the inverted data to the peripheral circuit, based on the conversion control signal.

13. A memory system comprising:
a semiconductor memory device including a plurality of memory blocks; and
a controller configured to control an operation of the semiconductor memory device,
wherein original data from a host is converted based on a block address of a target memory block and a program-erase count value of the target memory block, and the converted data is written to the target memory block.

14. The memory system of claim 13, wherein the controller includes a randomizer configured to generate randomized data, based on the block address and the program-erase count value.

15. The memory system of claim 14, wherein the semiconductor memory device writes the randomized data to the target memory block.

16. The memory system of claim 14, wherein the randomizer:
generates temporary data by performing an operation on a randomizing seed and the original data; and
inverts the temporary data, based on the program-erase count value, and outputs the inverted result as the randomized data.

17. The memory system of claim 14, wherein the randomizer:
generates a conversion seed by converting a randomizing seed corresponding to the block address, based on the program-erase count value; and
performs an operation on the conversion seed and the original data, and outputs the operated result as the randomized data.

18. The memory system of claim 13,
wherein the controller randomizes the original data, based on the block address, and
wherein the semiconductor memory device inverts the randomized data, based on the program-erase count value, and writes the inverted data to the target memory block.

19. The memory system of claim 18,
wherein, when the program-erase count value is even, the semiconductor memory device writes the randomized data to the target memory block, and
wherein, when the program-erase count value is odd, the semiconductor memory device inverts the randomized data and then writes the inverted data to the target memory block.

20. The memory system of claim 18,
wherein, when the program-erase count value is odd, the semiconductor memory device writes the randomized data to the target memory block, and
wherein, when the program-erase count value is even, the semiconductor memory device inverts the randomized data and then writes the inverted data to the target memory block.

21. A memory system comprising:
a memory device including a memory block; and
a controller suitable for:
randomizing data;
converting the randomized data according to a current status of the memory block; and
controlling the memory device to program the converted data into the memory block.

22. A memory system comprising:
a memory device including a memory block; and
a controller suitable for:
converting seed data according to a current status of the memory block;
randomizing data by using the converted seed data; and
controlling the memory device to program the randomized data into the memory block.

23. A memory system comprising:
a memory device including a memory block; and
a controller suitable for providing randomized data to the memory device,
wherein the memory device converts the randomized data according to a current status of the memory block, and programs the converted data into the memory block.
